(19) United States
(12) Patent Application Publication
(10) Pub. No.: US 2025/0054832 A1
(43) Pub. Date: Feb. 13, 2025

(54) CARRIER SUBSTRATE FOR ELECTRICAL COMPONENTS, AND METHOD FOR PRODUCING SUCH A CARRIER SUBSTRATE

(71) Applicant: ROGERS GERMANY GMBH, Eschenbach (DE)

(72) Inventors: Vitalij GIL, Hersbruck (DE); Johannes WIESEND, Kirchenthumbach (DE); Fabian WAGLE, Bayreuth (DE)

(21) Appl. No.: 18/718,949

(22) PCT Filed: Dec. 13, 2022
(86) PCT No.: PCT/EP2022/085608

§ 371 Date: Jun. 12, 2024

(30) Foreign Application Priority Data
Dec. 14, 2021 (DE) 10 2021 132 945.0

(51) Int. Cl. H01L 23/373; H01L 21/683; H01L 23/473; H01S 5/024

(52) U.S. Cl. CPC H01L 23/3735; H01L 21/6835; H01L 23/473; H01S 5/02423; H01L 2221/68372

(57) ABSTRACT

Carrier substrate (1) for electrical components (4), comprising:
a heat sink (20), and
a ceramic element (71), wherein the ceramic element (71) is bonded to the heat sink (20) at least in sections,
wherein a bonding layer free of solder material is formed in the manufactured carrier substrate (1) between the heat sink (20) and the ceramic element (71), and
wherein a adhesion agent layer of the bonding layer has a sheet resistance which is greater than 5 ohm/sq, more preferably greater than 10 ohm/sq and most preferably greater than 20 ohm/sq.

### CROSS REFERENCE TO RELATED APPLICATIONS

This application is a National Stage application of PCT/EP2022/085608, filed Dec. 13, 2022, which claims the benefit of German Application No. DE 10 2021 132 945.0, filed Dec. 14, 2021, both of which are incorporated by reference in their entirety herein.

### BACKGROUND

The present invention relates to a carrier substrate for electrical components and a method for the production of such a carrier substrate.

Heat sinks for cooling electrical or electronic components, in particular semiconductors such as laser diodes, are well known from the prior art. The electrical or electronic components generate heat during operation, which is dissipated by the heat sink in order to ensure the long-term functionality of the electrical or electronic components. This applies in particular to laser diodes, where temperature differences of just a few ° C. can lead to significant impairments in performance and/or service life.

To cool the components, the heat sinks, which are usually bonded to the components, typically have a cooling fluid channel system through which a cooling fluid is channelled during operation in order to absorb and remove heat emanating from the electrical or electronic component. Preferably, a fin structure is used here, in which several bridge-like elements protrude into the cooling fluid channel system in order to provide the largest possible contact surface with the cooling fluid, thus improving the heat transfer from walls that limit the cooling fluid channel system or protrude into it to the cooling fluid. For example, the heat sinks are used to cool laser diodes.

It is also common to use heat sinks to cool printed circuit boards that are formed as metal-ceramic substrates.

To insulate the electrical components on the component side, insulating elements are typically embedded in the carrier substrates in which the heat sinks are integrated, wherein ceramic elements have proven to be particularly favourable due to their high insulation strength. However, the choice of material for the ceramic elements used for electrical insulation is limited by the manufacturing process of the carrier substrates, in particular by the bonding of the heat sink, so that, for example, the positive thermal properties of a Si₃N₄ substrate cannot be utilised for such carrier substrates.

The present invention therefore sets itself the object of providing improved carrier substrates that can achieve optimised heat dissipation, in particular due to their improved material selection with regard to the ceramic element.

### SUMMARY

This object is achieved by a carrier substrate as described herein and a method as described herein. Further design and embodiments can be found in the description and the figures.

According to a first aspect of the present invention, a carrier substrate for electrical components is provided, which has the following:
a heat sink, and
a ceramic element, wherein the ceramic element is bonded to the heat sink at least in sections,
   wherein a bonding layer free of solder material is formed in the manufactured carrier substrate between the heat sink and the ceramic element, and
   wherein a adhesion agent layer of the bonding layer has a sheet resistance which is greater than 5 ohm/sq, more preferably greater than 10 ohm/sq and most preferably greater than 20 ohm/sq.

### BRIEF DESCRIPTION OF THE DRAWINGS

Further advantages and properties result from the following description of preferred embodiments of the subject-matter according to the invention with reference to the attached figures. It is shown:

It is shown:

FIG. 1 schematic representation of a carrier substrate according to an exemplary embodiment of the present invention,

FIG. 2: schematic exploded view of a carrier substrate for an exemplary embodiment of the present invention,

FIG. 3 schematic representation of a first metal layer for a heat sink of FIG. 1,

FIG. 4 schematic representation of a carrier substrate for a further exemplary embodiment of the present invention, and

FIG. 5 to FIG. 8: detailed representation of the system comprising the carrier substrate with a distribution structure.

### DETAILED DESCRIPTION

In contrast to the carrier substrates known from the prior art, which have a heat sink and a ceramic element, it is provided according to the invention that a bonding layer free of solder material formed between the ceramic element and the heat sink is provided, which has a comparatively high sheet resistance. In other words, the bonding process used for bonding to the ceramic element has dispensed with a solder material and the manufacturing process has also resulted in a comparatively high sheet resistance being produced. This is particularly the case if the bonding to the ceramic element is carried out via hot isostatic pressing, more preferably hot isostatic pressing in which an active metal layer is arranged between the ceramic element and the metal layer to be bonded. This results in a bonding layer with a homogeneously distributed, comparatively low thickness (dimensioned along a stacking direction), which is in particular essentially determined or established by the adhesion agent layer.

A bonding layer free of solder material is to be understood in particular as such a bonding layer which is essentially or exclusively due to active metal and has no additional components which are due to a solder base material or a solder material containing active metal. In other words, more preferably, the bonding layer is formed essentially exclusively by the adhesion agent layer. As a result of the bonding process, an active metal layer in use becomes the bonding layer or part of the bonding layer.

Together with other parameters, such as the purity of the applied active metal layer and/or the roughness of the ceramic element, this contributes to a correspondingly developed sheet resistance. The advantage of not using a solder material when bonding the metal layer to the ceramic element (which in turn leads to the properties according to the claim) is that the temperatures required during the bonding process of the heat sink do not affect the bond between the metal layer and the ceramic element. The heat sink is bonded in a subsequent step following the bonding of the metal layer to the ceramic element, in which temperatures prevail that would cause the solder material to melt again if it were bonded via a solder material. In contrast to bonding layers created from solder material, i.e. bonding layers containing solder material, such bonding layers, which have the required sheet resistance, prove to be resistant to the temperatures present when bonding the heat sink to the metal-ceramic substrate. This in turn makes it advantageously possible to provide carrier substrates whose ceramic elements were previously unsuitable because they could only be bonded to a metal layer via a solder system, in particular solder systems that cannot withstand the temperatures required for bonding the heat sink.

It is emphasised that the described bonding layer is arranged between the heat sink and the ceramic element and, in particular, is formed on the cooling side of the ceramic element or is adjacent thereto. In particular, it is emphasised that, due to the manufacturing process, at least one metal section may be formed between the heat sink (in the form in which it is provided to the bonding process) and the ceramic element, or between the heat sink that has been installed and the ceramic element, as viewed in the stacking direction. If this metal section is made of the same material as the heat sink used in the manufacturing process, there may be a smooth transition between the heat sink and this metal section. The person skilled in the art will therefore either attribute this metal section, which is not attributable to the heat sink originally used but is integrally joined to the heat sink provided in the manufactured state, to the heat sink in the manufactured state or recognise that a further metal layer or a further metal section may also be formed between the heat sink and the carrier substrate.

The carrier substrate can be a printed circuit board, for example, in which conductor paths and/or connecting areas are formed on its component side, which are provided for bonding electrical components, in particular for forming electrical circuits. Alternatively, it is conceivable that the carrier substrate is a cooling system with which, for example, a laser diode or a laser diode arrangement can be cooled. Preferably, it is provided that the heat sink is formed by stacking at least a first and second metal layer on top of each other, which in turn are joined together by a direct bonding method. Corresponding voids within the first metal layer and the second metal layer can be used to create a cooling channel system through which a cooling fluid, for example a cooling liquid or a cooling gas, can be channelled during operation in order to dissipate heat from the carrier substrate. It is also conceivable that the heat sink is manufactured differently and/or provides a fin structure, for example. Regardless of the form of providing, it can be an open or a closed cooling structure in the heat sink.

To determine the sheet resistance, it is provided that the metal layer and possibly a solder base layer are first removed from the manufactured carrier substrate, for example by etching. By means of a four-point measurement, a sheet resistance is then measured on the upper side or bottom side of the carrier substrate freed from the at least one metal layer and the solder base layer. In particular, the sheet resistance of a material sample is to be understood as its resistance in relation to a square surface area. It is customary to characterise the surface resistance with the unit ohm/sq(square). The physical unit of sheet resistance is Ohm.

Preferably, the carrier substrate is formed as a printed circuit board in which, in the manufactured state, the at least one metal layer bonded to the ceramic element is structured. For example, it is provided for this purpose that after the bonding step, structuring is also carried out, for example by lasering, etching and/or mechanical processing, with which conductor paths and/or connections for electrical or electronic components are realised. Preferably, a further metal layer, in particular a backside metallization, is provided on the ceramic element on the side opposite the metal layer on a manufactured metal-ceramic substrate. The backside metallisation preferably serves to counteract deflection and the heat sink, which in turn is bonded to the backside metallization, serves to effectively dissipate heat that emanates during operation from electrical or electronic components that are bonded to the printed circuit board or the metal-ceramic substrate.

Copper, aluminium, molybdenum, tungsten, nickel and/or their alloys, such as CuZr, AlSi or AlMgSi, as well as laminates such as CuW, CuMo, CuAl and/or AlCu or MMC (metal matrix composite), such as CuW, CuM or AlSiC, are conceivable as materials for the metal layer in the metal-ceramic substrate or for the metal of the heat sink. Furthermore, it is more preferably provided that the at least one metal layer on the manufactured metal-ceramic substrate is surface-modified, in particular as component metallisation. Surface modification may be, for example, sealing with a noble metal, in particular silver and/or gold, or (electroless) nickel or ENIG (“electroless nickel immersion gold”) or edge encapsulation on the metallisation to suppress crack formation or expansion.

Preferably, it is provided that a thickness of the bonding layer or adhesion agent layer measured in the stacking direction, averaged over a plurality of measuring points within a predetermined area or in a plurality of areas which course or run parallel to the main extension plane, has a value which is less than 1000 nm, more preferably less than 600 nm and most preferably less than 350 nm. When the term “plurality of areas” is used, it is meant in particular that the metal layer is subdivided into areas of the same size and at least one value, more preferably several measured values, for the thickness are recorded in each of these areas subdividing the metal layer. The thicknesses determined in this way at different points are arithmetically averaged

In particular, the ceramic element has a material composition that cannot be bonded via a direct bonding method. Preferably, it is provided that the ceramic element comprises silicon nitride. In particular, it is provided that the ceramic element comprises more than 60 weight percent, more preferably more than 80 weight percent and most preferably more than 90 weight percent silicon nitride. Silicon nitride proves to be particularly advantageous because it leads to a high thermal shock resistance and provides a high flexural strength. In addition, the forming of thermomechanical stresses is reduced due to the increased thermal expansion coefficient. In addition, improved thermal conductivity can improve the efficiency of heat dissipation. It proves to be particularly advantageous that silicon nitride can also be used for such carrier substrates due to the hot isostatic pressing used in the production of the metal-ceramic substrate. Finally, silicon nitride cannot be bonded to a metal layer, in particular a copper layer, using a direct bonding method and the required soldering materials have a smelting temperature of below 1000° C., so that they would melt the soldering material again in a direct bonding method for the heat sink. Thus, the method, which is structurally reflected in the solderless bonding layer with the increased surface resistance, also enables the use of silicon nitride in a corresponding carrier substrate. Furthermore, it is preferably provided that the ceramic element, in particular the silicon nitride ceramic, has a thermal conductivity that is greater than 90 W/mK, more preferably greater than 110 W/mK and most preferably greater than 120 W/mK. Furthermore, it is conceivable that the ceramic element has a thickness that is less than 300 μm, more preferably less than 250 μm and most preferably less than 200 μm.

Alternatively, the ceramic element has Al₂O₃, AlN, an HPSX ceramic (i.e. a ceramic with an Al₂O₃ matrix comprising an x-percentage of ZrO₂, for example Al₂O₃ with 9% ZrO₂=HPS9 or Al₂O₃ with 25% ZrO₂=HPS25), SiC, BeO, MgO, high-density MgO (>90% of the theoretical density), TSZ (tetragonally stabilised zirconium oxide) as material for the ceramic. It is also conceivable that the ceramic element is formed as a compound or hybrid ceramics, in which several ceramic layers, which differ in terms of their material composition, are arranged on top of one another and joined together to form a ceramic element in order to combine various desired properties. Preferably, the ceramic element is free of parylene.

In particular, it is provided that the heat sink is bonded to the ceramic element via a backside metallization and preferably the adhesion agent layer is formed between the backside metallization and the ceramic element. The backside metallization to be assigned to the heat sink is bonded to the ceramic element in a preparatory manufacturing step and the heat sink is only bonded after the backside metallisation has been bonded. As a result, the backside metallisation section and the heat sink are subjected to different temperature treatments, which are reflected in different grain sizes. As a result, these sections can be recognised on the finished substrate.

Preferably, it is provided that a grain size in the backside metallization differs from a grain size in the heat sink. Since the backside metallization can also be achieved in the manufacturing process during hot-sostatic pressing by fixing the metal layer to be bonded in a metal bag and this results in the metal layer and part of the metal bag being bonded, structural differences can also be detected if metal materials of different purity are used for the metal layer and the metal bag.

For example, the bonding layer between the backside metallization and the ceramic element contains an active metal content that can be traced back to an active metal layer that is used in the manufacturing process.

Furthermore, it is conceivable that the backside metallization protrudes along a main extension plane relative to the heat sink. Since the heat sink is bonded to the backside metallization, which is already bonded to the ceramic element, and preferably does not extend via the entire backside of the ceramic element, the backside metallization can be made larger. This means that the backside metallization, which is preferably bonded to the ceramic element over the entire surface, does not have to be partially removed again. This also simplifies the positioning of the heat sink in relation to the backside metallization during production, as it is not necessary to have an absolutely congruent arrangement.

It is preferably provided that the heat sink is preferably formed from at least a first metal layer and a second metal layer, which are joined on top of one another by means of a direct bonding method, in particular a solderless direct bonding method, wherein the first metal layer and/or the second metal layer have recesses which form a cooling channel in the manufactured carrier substrate. It is also conceivable that the cooling channel extends as far as the ceramic element and/or that a residual metal layer thickness is provided almost exclusively and, more preferably, without exception, between the ceramic element and the cooling channel. For the forming of a cooling channel extending to the carrier substrate or to the ceramic element, it is provided that in the manufacturing process, after the bonding of a backside metallization to the ceramic element, the backside metallization is structured in order to expose corresponding areas on the ceramic element before the bonding process of the heat sink to the backside metallization takes place.

Preferably, the distance between the side surfaces limiting a cooling channel is less than 0.5 mm, more preferably less than 0.4 mm and most preferably less than 0.3 mm. In particular, this refers to side surfaces that are spaced apart in a direction parallel to the main extension plane. Such comparatively thin channels and distances between side surfaces can be produced, for example, by eroding or wire-cutting in the respective metal layers. Such thin cooling channels prove to be particularly advantageous because they ensure high efficiency in the transfer of heat and can also provide a particularly evenly and homogenously distributed cooling or heat transfer possible on the cooling side.

Preferably, it is provided that a thickness of the bonding layer or the adhesion agent layer measured in the stacking direction, averaged over a plurality of measuring points within a predetermined area or in a plurality of areas which course or run parallel to the main extension plane, has a value which is less than 1000 nm, more preferably less than 600 nm and most preferably less than 350 nm. Where the term “plurality of areas” is used, it is meant in particular that the metal layer is subdivided into areas of as equal a size as possible and at least one value, more preferably several measured values, for the thickness are recorded in each of these areas subdividing the at least one metal layer. The thicknesses determined in this way at different points are arithmetically averaged.

Compared to the carrier substrates known from the prior art, a comparatively thin bonding layer is thus formed between the at least one metal layer and the ceramic element. It is provided that, in order to determine the relevant thickness of the bonding layer, the measured thicknesses are averaged via a plurality of measuring points which lie within a predetermined or defined area or the plurality of areas.

In particular, it is provided that the adhesion agent layer comprising an active metal has a substantially constant thickness. In particular, the measured values of the thickness determined within the area or areas have a distribution to which a standard deviation is to be assigned which is less than 0.2 μm, more preferably less than 0.1 μm and most preferably less than 0.05 μm. In particular, the physical and/or chemical vapour deposition of an active metal layer and the resulting bonding layer make it possible to achieve a homogeneous and uniformly distributed thickness of the bonding layer, which consists in particular only of the adhesion agent layer. The adhesion agent layer can also have a constant thickness if it is formed in addition to the solder base material.

A further object of the present invention is a method for the production of a substrate according to the invention comprising: bonding a backside metallization and preferably the component metallization to a ceramic element to form a metal-ceramic substrate by means of hot isostatic pressing,
providing a heat sink, in particular a heat sink with a cooling channel structure, and
bonding the heat sink to the backside metallization by means of a direct bonding method, in particular a DCB method.

All the described advantages and properties of the carrier substrate can be applied and transferred analogously to the method and vice versa.

Preferably, it is provided that during hot isostatic pressing, the metal container or a metal layer is exposed to a gaseous pressure of between 100 and 2000 bar, more preferably between 150 and 1200 bar and most preferably between 300 and 1000 bar and a processing temperature of 300° C. up to a smelting temperature of a metal layer, in particular up to a temperature below the smelting temperature. Advantageously, it has been shown that it is thus possible to bond a metal layer, for example the component metallization and/or backside metallization, to the ceramic element without the required temperatures of a direct metal bonding process, for example a DCB or a DAB process, and without a solder base material or solder material used in active soldering. In addition, the use or application of an appropriate gaseous pressure makes it possible to produce a metal-ceramic substrate that is as void-free as possible, i.e. without gas inclusions between the metal layer and the ceramic element. In particular, process parameters are used which are mentioned in DE 2013 113 734 A1 and to which explicit reference is hereby made. It has also been shown that the joining between the ceramic element and the metal layer produced in this way can withstand temperatures in excess of 1050° C.

In particular, the present method is characterised by the fact that the bonding of the backside metallization to the ceramic element is carried out as part of a hot isostatic pressing process and not as part of a soldering process. This makes the bond between the component metallization or backside metallization on one side and the ceramic element on the other side more resistant, in particular more resistant with regard to temperatures that are used when bonding the heat sink to the metal-ceramic substrate. In particular, it is provided that the heat sink is bonded to the backside metallization of the metal-ceramic substrate produced by hot isostatic pressing. As a result, it is no longer necessary to rely on solder-based bonding methods in order to use ceramic elements that cannot be bonded to a metal layer via a direct bonding method. Therefore, the method described also enables the bonding of such ceramic elements that could not previously be used to form the carrier substrates described, as the solder materials used would otherwise be damaged or even destroyed in the bonding process of the heat sink.

Preferably, it is provided that a void in a first metal layer or a second metal layer is realised by etching, eroding and/or milling and at least the first and second metal layers are joined together to form the heat sink. This provides the heat sink for bonding, wherein the corresponding heat sink provides a cooling channel system via which a cooling fluid can be guided in order to dissipate the heat in the manufactured carrier substrate.

Preferably, it is provided that an active metal layer is arranged between the ceramic element and the component metallization or the backside metallization on the other side. This provides a particularly strong bond between the backside metallization and the ceramic element during hot isostatic pressing, wherein the active metal layer contributes significantly to forming the adhesion agent layer or the bonding layer. In particular, it is provided that the active metal layer becomes the adhesion agent layer, especially the bonding layer, after the manufacturing process.

In particular, by using a separately designed active metal layer, it is possible to make it comparatively thin, thus realising the comparatively thin thicknesses of the bonding layer according to the claim(s), in particular averaged via different measurement values within the defined area or areas. Examples of an active metal are titanium (Ti), zirconium (Zr), hafnium (Hf), chromium (Cr), niobium (Nb), cerium (Ce), tantalum (Ta), magnesium (Mg), lanthanum (La) and vanadium (V). It should be noted that the metals La, Ce, Ca and Mg can easily oxidise. It should also be noted that the elements Cr, Mo and W are not classic active metals, but are suitable as a contact layer between Si₃N₄ and the at least one metal layer or the solder system or solder material, as they do not form intermetallic phases with the at least one metal layer, for example copper, and do not have solid solubility.

Preferably, the active metal is deposited on the solder base material and/or the at least one metal layer and/or the ceramic element by means of physical and/or chemical vapour deposition, for example by means of sputtering, in order to produce comparatively thin active metal layers, which in turn lead to a comparatively thin bonding layer, in particular to a homogeneous and thin adhesion agent layer. It is also conceivable to provide the active metal layer on the ceramic element and/or the metal layer for component metallization and/or backside metallization with the use of a plasma, in a vacuum and/or by means of vapour deposition. It is also conceivable to realise the active metal layer by electroplating. Most preferably, the active metal layer is provided as a foil.

The active metal layer can be provided in particular by means of gas-physical deposition, thus enabling comparatively thin active metal layers to be realised, which can also contribute to achieving the required surface resistance. Galvanic, electroless and/or thermal deposition or deposition by means of cold gas spraying is also conceivable.

Preferably, it is provided that a ratio between a thickness of the active metal layer and a thickness of the first metal layer and/or second metal layer has a value between 0.0001 and 0.005, more preferably between 0.005 and 0.003 and most preferably between 0.001 and 0.0015. Accordingly, a comparatively thin active metal layer is advantageous in order to realise an effective bonding layer while limiting the consumption of active metal.

Preferably, it is provided that the bonding of the heat sink to the backside metallization is realised by hot isostatic pressing after forming the metal-ceramic substrate. The metal-ceramic substrate is formed first in order to ensure that bending due to thermomechanical stresses in the metal-ceramic substrate is prevented during the forming process of the metal-ceramic substrate by ensuring that the thicknesses of the backside metallization and the component metallization are as equal or comparable as possible. In other words, a metal-ceramic substrate with component metallization and backside metallization is first manufactured to prevent bending of the metal-ceramic substrate after or during the bonding process, which would be the result of the different thermomechanical expansion coefficients of the ceramic element and metal layer. It is then easier to bond a heat sink to such an essentially flat and even metal-ceramic substrate, particularly via its cover layer. Otherwise, the metal-ceramic substrate would have to be laboriously straightened, if this is still possible. In addition, it has been shown that metal layers larger than 0.4 mm that are bonded to the ceramic element cause greater thermomechanical stresses after cooling, which also remain after cooling.

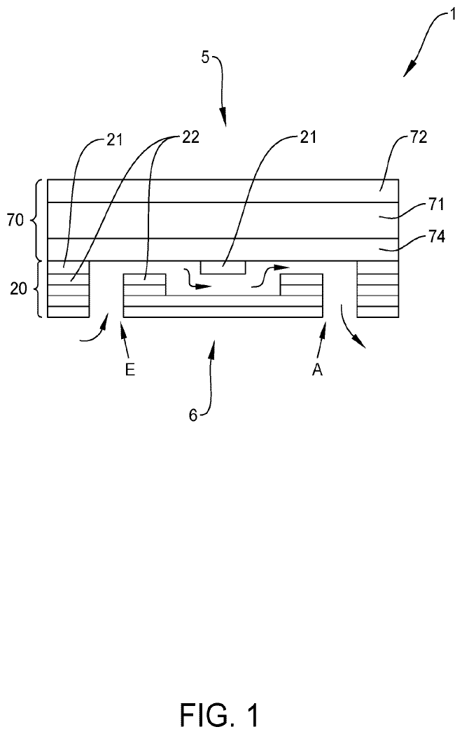

FIG. 1 schematically shows a carrier substrate 1 according to a preferred embodiment of the present invention. Such carrier substrates 1 are provided in particular to allow electrical components 4 to be bonded at their component side 5. For example, the carrier substrate 1 may be a printed circuit board in which a plurality of connecting areas and conductor paths and contact areas are provided via which circuits are realised. It is also conceivable that the carrier substrate 1 is essentially a cooling structure that is provided to specifically cool an electrical component, such as a laser diode or a laser diode arrangement. In order to dissipate the heat generated by the electrical components 4 during operation, the carrier substrate 1 comprises a heat sink 20. This heat sink 20 is formed on a cooling side 6 opposite the component side 5. Preferably, the heat sink 20 is a metallic structure formed by stacking at least a first metal layer 21 and a second metal layer 22 on top of each other and then joining the at least one metal layer 21 and the second metal layer 22. It is possible to realise a channel system within the heat sink 20 by means of recesses which are embedded in the first metal layer 21 and/or second metal layer 22. A cooling fluid, for example a cooling gas or a cooling liquid, can be guided through this channel system in order to dissipate heat from the carrier substrate 1 accordingly. To insulate the electrical components 4, in particular from the metal heat sink 20, the carrier substrate 1 comprises a ceramic element 71. Preferably, it is provided that the carrier substrate 1 comprises a metal-ceramic substrate 70 and the heat sink 20, which are joined together to form the carrier substrate 1. It is preferably provided that the metal-ceramic substrate 70 provides a component metallization 72 on the component side of the ceramic element 71 and a backside metallization 74 on a cooling side 6 of a ceramic element 71 of the metal-ceramic substrate 70 opposite the component side 5. The thicknesses of the component metallization 72 and the backside metallization 74 correspond to each other, in order to compensate in particular in the manufacturing step in which bonding of the component metallization 72 and the backside metallization 74 to the component side of the ceramic element 71 is carried out for thermomechanical stresses caused by the different coefficients of thermal expansion of the backside metallization 74/component metallization 72 on the one side and the ceramic element 71 on the other side. Without such compensation, the metal-ceramic substrate 70 tends to deflect. It is therefore preferably provided that the heat sink 20 is bonded to the metal-ceramic substrate 70, in particular to the backside metallization 74 of the already manufactured metal-ceramic substrate 71. The bonding of a cover layer of the heat sink 20 to the backside metallization 74 is preferably carried out by a direct bonding method, in particular by a solderless direct bonding method, which requires temperatures above 1,068° C. in order to produce a eutectic that is formed between the backside metallization 74 and the cover layer of the heat sink 20. In the embodiment shown, the first metal layer 21 forms the cover layer.

Preferably, it is provided that the first metal layer 21 and the second metal layer 22 are already compounded with each other during the joining process of the heat sink 20 to the metal-ceramic substrate 1. Alternatively, it is conceivable that the bonding between the first metal layer 21 and the second metal layer 22 and the bonding between the cover layer of the heat sink 20 and the backside metallization 74 are performed simultaneously or at least overlapping in time. It is conceivable that the first metal layer 21 forms the cover layer (see embodiment of FIG. 1) and/or the cover layer is an additional layer that is bonded to an upper side of the heat sink 20. For example, it is conceivable that the cover layer forms a continuous metal layer without voids.

The necessity of bonding the heat sink 20 to the metal-ceramic substrate 1, in particular to the backside metallization 74, by means of a direct bonding method and therefore at the corresponding temperatures means that the bond already created between the ceramic element 71 and the component metallization 72 or the backside metallization 74 must also withstand the manufacturing conditions for bonding the heat sink 20 to the metal-ceramic substrate 1. Otherwise, the manufacturing conditions used, which are required as part of the bonding of the heat sink 20 to the metal-ceramic substrate 70, would again loosen or at least impair the bond between the backside metallization 74 or component metallization 72 and the ceramic element 71. This is particularly the case if solder materials whose smelting temperature is below 1000° C. have to be used for bonding the component metallization 72 or the backside metallization 74 to the ceramic element 71.

However, this also has the consequence that such ceramic elements 71 are excluded from use in the carrier substrates 1 described, which can only be bonded to a metal layer (i.e. to component metallization 72 or backside metallization 74) via a solder material. This applies, for example, to silicon nitride, which cannot be bonded to a metal using a direct bonding method. In order to also use such ceramic elements in the described carrier substrates, which would otherwise have to be excluded, the present invention provides for the bonding of the component metallization or the backside metallization to the ceramic element by a solderless bonding process, in particular a solderless hot isostatic pressing, to the ceramic element 71.

In particular, it is provided that, as part of the bonding process, an active metal layer is arranged between the ceramic element 71 and the component metallization 72 and/or between the ceramic element 71 and the backside metallization 74 during hot isostatic pressing. This is deposited on the component side 5 or the cooling side 6 of the ceramic element 71 and or on the component metallization 72 and/or backside metallization 74, for example by a gas-physical deposition method, for example by a sputtering process, or an electrochemical method, for example before the hot isostatic pressing. It has been found that a bond between ceramic element 71 and component metallization 72 or backside metallization 74 is possible, in particular also for those ceramic elements 71 that are not accessible for a direct metal bonding process. At the same time, it has been found that the joining can also withstand the temperatures required for the direct bonding method of the heat sink 20 to the metal-ceramic substrate 70. This is due in particular to the fact that the bonding between the ceramic element and the metal layer can be carried out without solder material or solder base material in this case.

It is emphasized once again that the active metal layer is an active metal layer whose proportion of active metal is greater than 15 weight percent, more preferably greater than 30 weight percent and most preferably greater than 70 weight percent. It is therefore not an active metal-containing solder layer, as is otherwise usual, when bonding a component metallization 72 to a ceramic element 71. This makes it possible, for example, to use ceramic elements 71 that are particularly favourable due to their high thermal conductivity or advantageous for forming a corresponding carrier substrate 1. This applies in particular to such carrier substrates 1 whose ceramic element 71 comprises silicon nitrides or is formed from more than 80% silicon nitride.

The bonding method described is preferably characterised by the fact that the bonding layer
has a bonding layer between the ceramic element 71 and the component metallisation 72 and/or between ceramic element 71 and backside metallization 74 whose sheet resistance is greater than 5 ohm/sq, more preferably greater than 15 ohm/sq and most preferably greater than 20 ohm/sq. The sheet resistance described is in particular the result of a uniformly applied active metal layer and bonding via hot isostatic pressing. Bonding layers that are produced with the use of a solder material with an active metal component, on the other hand, have a lower sheet resistance. In particular, it is provided that only a adhesion agent layer is formed between backside metallization 74 or component metallization 72 and ceramic element 71 as a bonding layer, i.e. no subregions can be identified in the manufactured carrier substrate 1 that are attributable to a solder material.

Since the bonding process of the backside metallization 74 to the cover layer of the heat sink 20 as part of a direct bonding method means that no boundary line/transition area can be identified at the manufactured transition between the backside metallization 74 and the upper side of the heat sink 20, the backside metallization 74 is part of the heat sink 20 in the manufactured state. Thus, the sheet resistance is formed between the ceramic element 71 and the heat sink 20, to which the original backside metallization 74 of the metal-ceramic substrate 1 is to be added in the manufactured state. Thus, the metal-ceramic substrates produced according to the method of the invention can be recognised by the fact that a corresponding sheet resistance is formed between the ceramic element 71 and the heat sink 20. In addition, it is provided in particular that a bonding layer is formed which is exclusively formed as a adhesion agent layer which is not attributable to a solder material.

Furthermore, a meander or loop-shaped channel system is formed in FIG. 1, into which, for example, a cooling fluid can be introduced via an inlet E, which is guided through the heat sink 20 in a loop or meander-shaped movement to finally leave the heat sink 20 again through an outlet opening A. In the following figures, further examples are given of heat sinks which could be provided for certain embodiments of the invention and which can be bonded to a metal-ceramic substrate 70, in particular its backside metallization.

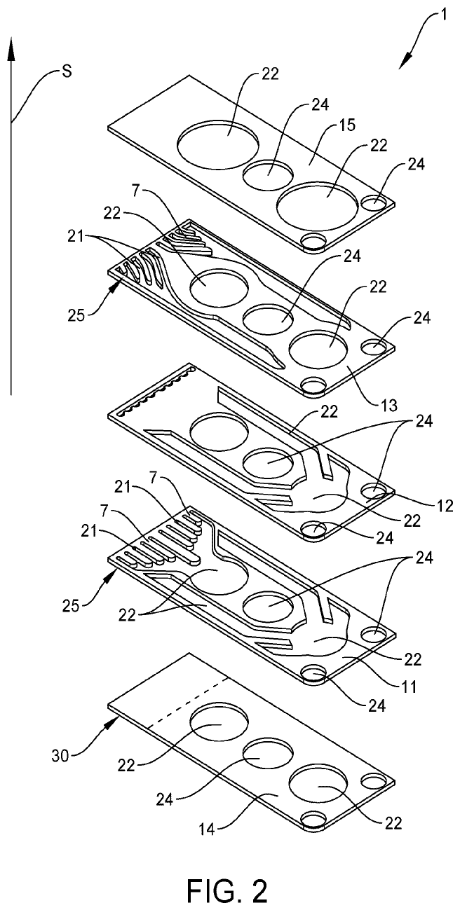

FIG. 2 schematically illustrates an exploded view of a heat sink 1 according to a first preferred embodiment for a subject-matter according to the present invention. In particular, the heat sink 1 is one that is provided for cooling an electronic or electrical component (not shown), in particular a semiconductor element, and most preferably a laser diode. To cool the electrical or electronic component, the manufactured heat sink 1 forms a cooling fluid channel system through which a cooling fluid can be conducted during operation, so that the cooling fluid can absorb and remove heat emitted by the electronic or electrical component during operation.

For this purpose, a supply area and a discharge area are preferably provided in the heat sink 1, in particular in the cooling fluid channel system, (not shown), wherein the cooling fluid is introduced via the supply area and is discharged again via the discharge area. Preferably, the cooling fluid channel system is provided in such a way that the cooling fluid 1 passes a fin structure 25 during the transition from the supply area to the discharge area, which in particular projects into the cooling fluid channel system. The fin structure 25 is preferably a web-like element 7 that protrudes into the cooling fluid channel system in order to provide the largest possible contact surface for the fluid, so that effective heat transfer from the web-like element 7 or the wall of the cooling channel system to the fluid is possible.

Preferably, the heat sink 1 comprises at least one first metal layer 11, at least one second metal layer 12 and/or at least one third metal layer 13. In order to form the cooling fluid channel system, the at least one first metal layer 11, the at least one second metal layer 12 and/or the at least one third metal layer 13 are structured by at least one void 21, 22 in such a way that they form the cooling fluid channel system by stacking one on top of the other or placing one on top of the other along the stacking direction S.

In particular, it is provided that the at least one first metal layer 11, the at least one second metal layer 12 and/or the at least one third metal layer 13 are each structured in a different manner or are provided with differently course voids 21, 22. In particular, it is provided that the at least one first metal layer 11, the at least one second metal layer 12 and/or the at least one third metal layer 13 forms at least one first part 21 in the at least one void 21, 22, which has the web-like elements 7, which in particular extend in a main extension plane HSE running perpendicular to the stacking direction S. In addition to the first part 21 of the at least one void 21, 22 in the at least one first metal layer 11, it is preferably provided that a second part 22 of the at least one void 21, 22 in the at least one first metal layer 11 is provided for the supply or discharge of the cooling fluid into the first part 21 or from the first part 21 or forms part of the supply area and/or discharge area.

The heat sink 1 is preferably limited in the stacking direction S by an upper cover layer 15 and a lower cover layer 14, wherein the at least one first metal layer 11, the at least one second metal layer 12 and/or the at least one third metal layer 13 is arranged between the lower cover layer 14 and the upper cover layer 15 as viewed in the stacking direction S. In particular, the formation of the at least one first metal layer 11, the at least one second metal layer 12 and/or the at least one third metal layer 13 is arranged in a sandwich-like manner between the upper cover layer 15 and the lower cover layer 14. In addition to the at least one void 21, 22, which is composed of the first part 21 and the second part 22, it is preferably provided that the heat sink 1 or the at least one first metal layer 11 has a further void 24, which is not part of the cooling fluid channel system, with the fin structure 25. Furthermore, it is preferably provided that a connecting area 30 is provided on the upper cover layer 15 and/or the lower cover layer 14. In particular, the electrical or electronic component is bonded to this connecting area 30, in particular as viewed in the stacking direction S, above or below the fin structure 25, which preferably extends in a direction perpendicular to the stacking direction S. In other words, the fin structure 25, in particular its web-like elements 7, extends below the connecting area 30 and preferably parallel thereto. Due to the corresponding arrangement of the fin structure 25 of the web-like elements 7 above or below the connecting area 30, the electrical or electronic component can be effectively cooled by means of the fin structure 25.

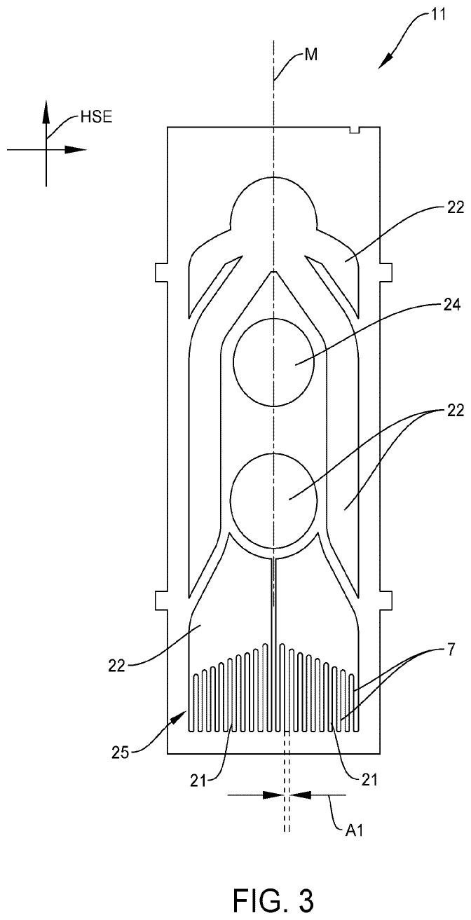

FIG. 3 shows a schematic representation of at least one first metal layer 11, which is installed, for example, in FIG. 1. In the embodiment shown, the fin structure 25 is formed from web-like elements 7, which extend to different lengths when viewed in the main extension plane HSE. In particular, a length of the web-like elements 7 increases towards a centre axis M of the at least one first metal layer 11. As a result, it is advantageously possible to maximise the cooling effect, in particular in the central region of the connecting area 30. Furthermore, it is conceivable that the web-like elements run parallel and/or at an angle to the centre axis M. Preferably, the shape of the web-like elements 7, in particular their length and/or inclination relative to the centre axis M along the main extension plane HSE, is determined or defined by the corresponding requirement profile for cooling the corresponding electrical or electronic component.

In order to achieve the smallest possible distance A1 between two neighbouring web-like elements 7, it is provided, for example, that the first part 21 of the at least one void 21, 22 in the at least one first metal layer 11 is produced by erosion, in particular spark erosion. In particular, this involves production by means of wire erosion.

Furthermore, it is provided that a second part 22 of the at least one void 21, 22 is carried out by etching. Preferably, the etching is performed in particular in large-area regions of the second part 22 of the void 21, 22, i.e. in the later supply and/or discharge regions formed for supplying and discharging the cooling fluid. In contrast, it is in particular provided that the eroding is provided for the finely structured moulding of the void 21, 22, i.e. the first part 21 of the void 21, 22. It has been found that this makes it possible to manufacture comparatively very small distances between the web-like elements 7 without having to rely on several first metal layers 11 with etched first parts 21 of the at least one void 21, 22, which would have to be stacked on top of one another in order to realise the smallest possible distance between two web-like elements 7. Preferably, the distance A1 between opposing side walls between two web-like elements 7 is less than 0.4 mm, more preferably less than 0.3 mm and most preferably less than 0.2 mm. This allows as many web-like elements 7 as possible to be integrated into the fin structure 25. Accordingly, it is possible to increase the cooling effect, since the contact surface between the cooling fluid and the wall of the cooling fluid channel system can be increased accordingly.

Preferably, the at least one first metal layer 11, the at least one second metal layer 12, the at least one third metal layer 13, the upper cover layer 15 and/or the lower cover layer 14 have a thickness, measured in stacking direction S, of between 0.2 and 0.7 mm, more preferably between 0.35 and 0.6 mm and most preferably between 0.3 and 0.4 mm. Preferably, the at least one first metal layer 11, the at least one second metal layer 12 and/or the at least one third metal layer 13 each form the same thickness. Furthermore, it is preferably provided that the at least one first metal layer 11, the at least one second metal layer 12 and/or the at least one third metal layer 13 are formed as part of a sintering process to form an integral cooling fluid channel system, in that the microstructures of the at least one first metal layer 11, the at least one second metal layer 12 and/or the at least one third metal layer 13 merge or fuse into one another by means of a corresponding temperature treatment.

Furthermore, it is provided that also the upper cover layer 15 and/or the lower cover layer 14 each have at least one void 21, 22 and/or a further void 24, wherein the upper cover layer 15 and/or the lower cover layer 14 are preferably free of web-like elements 7 or components of a later fin structure 25. The further voids 24 are preferably used for attaching or fixing the heat sink 1.

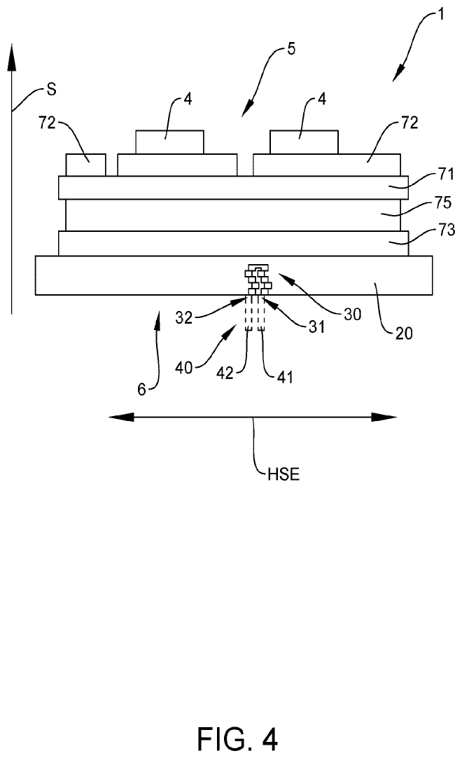

FIG. 4 schematically shows a metal-ceramic substrate 70 according to a further exemplary embodiment of the present invention. Such metal-ceramic substrates 1 preferably serve as carriers of electronic or electrical components 4, which can be connected to the metal-ceramic substrate 70. Essential components of such a metal-ceramic substrate 1 are a ceramic element 71 extending along a main extension plane HSE and a component metallisation 72 bonded to the ceramic layer 71. The ceramic element 71 is made of at least one material comprising a ceramic. The component metallisation 72 and the ceramic element are arranged on top of one another along a stacking direction S running perpendicular to the main extension plane HSE and are joined to one another with a material bond. In the manufactured state, the component metallisation 72 is structured on a component side 5 of the metal-ceramic substrate 70 to form conductor paths or connection points for the electrical components 4. In the embodiment shown, the metal-ceramic substrate 70 comprises a secondary layer 73 and a metallic intermediate layer 75 arranged between the ceramic element 71 and the secondary layer 73. The ceramic element 71, the metallic intermediate layer 75 and the secondary layer 13 are arranged on top of one another along the stacking direction S. Furthermore, it is provided that the metallic intermediate layer 75 is thicker than the ceramic element 71 and/or the secondary layer 73. Preferably, the metallic intermediate layer 75 is thicker than 1 mm, more preferably thicker than 1.5 mm and most preferably thicker than 2.5 mm. However, it is also conceivable that only a ceramic element 71 with a component metallization 72 and a backside metallization is formed for forming the metal-ceramic substrate. While the ceramic element 71 is preferably made of ceramic and is designed for forming sufficient insulation strength and for stiffening the metal-ceramic substrate 1, the secondary layer 73 may also be made of tungsten or molybdenum, for example, as no pronounced insulation strength is required here. This reduces the material costs. Alternatively, the secondary layer 73 is also made of a material comprising a ceramic.

A metallic heat sink 20 is provided on a cooling side 6 of the metal-ceramic substrate 1 opposite the component side 5. The metallic heat sink 20 is preferably bonded directly to the secondary layer 73. However, it is also conceivable that the heat sink 20 is bonded directly to a backside metallization of the metal-ceramic substrate 1 or to the ceramic element 71 of the metal-ceramic substrate 1. This makes it possible to avoid an interface that would otherwise form with a corresponding connecting material having a negative effect on the thermal conductivity and thus restricting heat removal from the component side 5 to the cooling side 6.

For example, the cooling structure 20 is bonded directly to the secondary layer 73, the backside metallization and/or to the ceramic element 71 via an AMB method, a DCB (direct copper bonding) or DAB (direct aluminium bonding) method. In particular, it is provided that a plurality of fluid channels 30 are integrated into the metallic cooling structure 20. For the sake of clarity, only a single one of these fluid channels 30 is shown as an example in FIG. 1. The fluid channels 30 serve to guide a fluid, in particular a cooling fluid, in a targeted manner within the metallic cooling structure 20. The fluid is supplied to the cooling structure 20 via a distribution structure 40 and discharged again via the distribution structure 40. Preferably, the distribution structure 40 has an inlet part 41 and an outlet part 42 for this purpose.

In particular, the fluid channel 30 has an inlet opening 31 and an outlet opening 32 spaced apart from the inlet opening 31. The inlet opening 31 and the outlet opening 32 are part of an outer side A of the cooling structure 20 facing the distribution structure 40. In particular, the inlet part 31 of the distribution structure 40 adjoins the inlet opening 31 and the outlet part 42 adjoins the outlet opening 32.

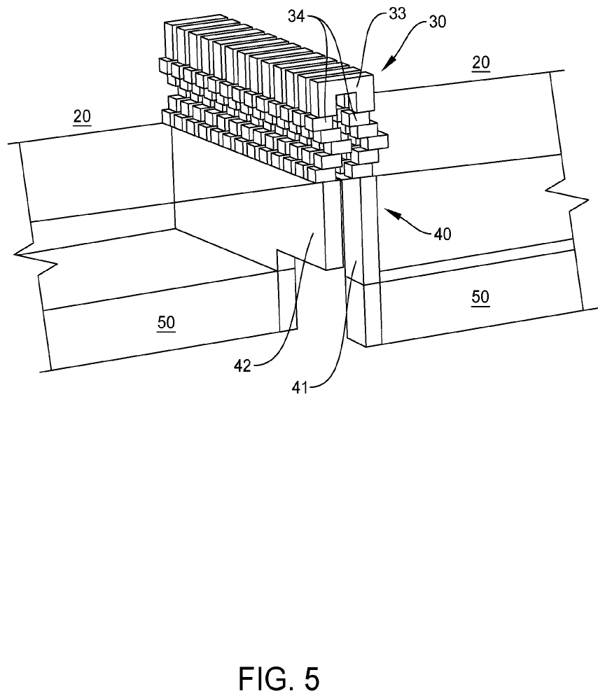

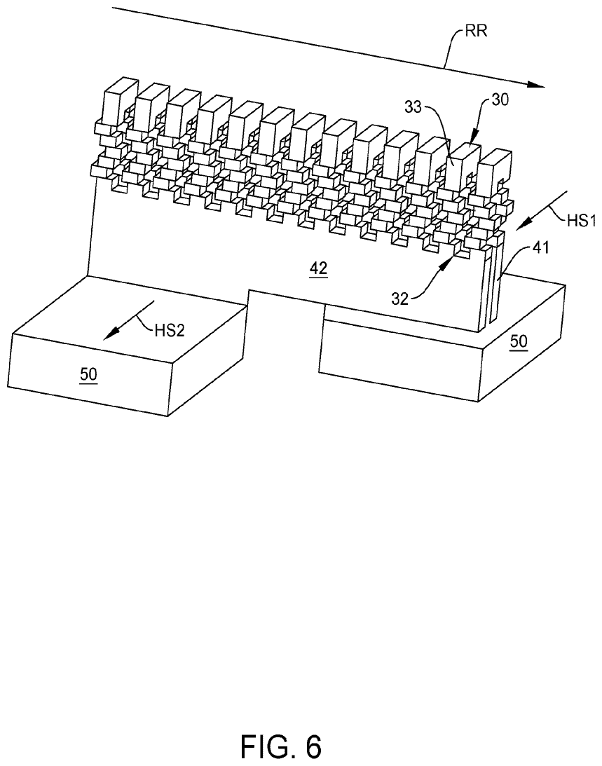

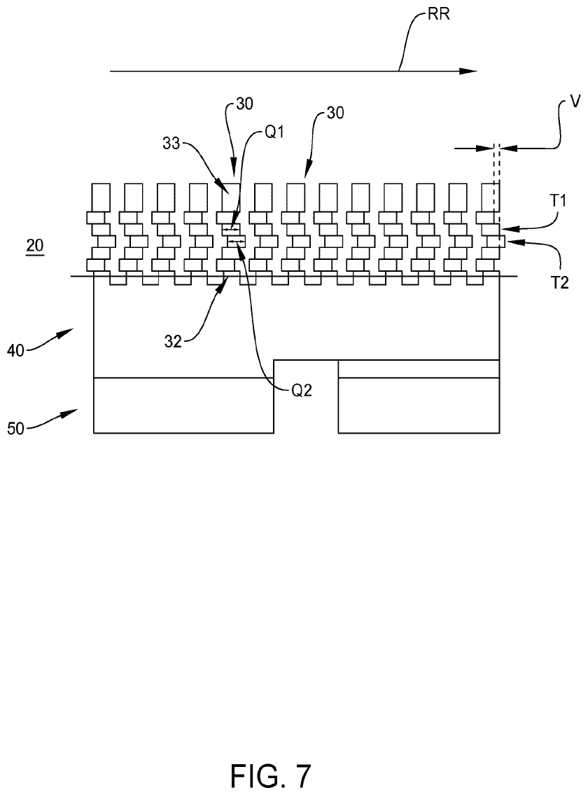

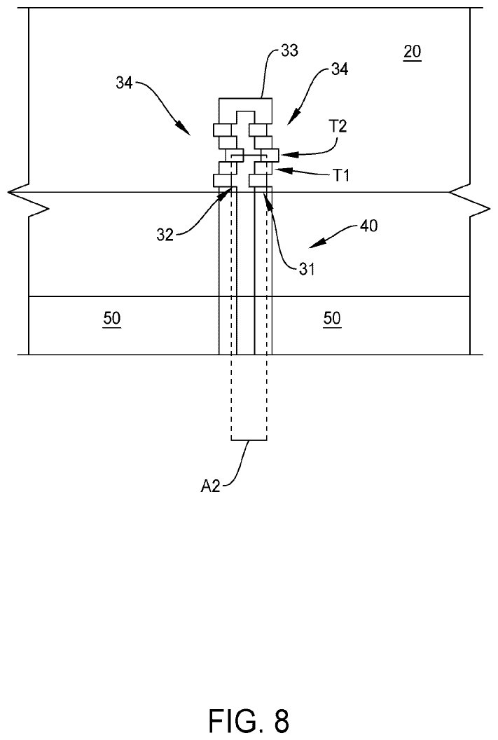

In FIGS. 4 to 6, only the metallic cooling structure 20 and the distribution structure 40 are shown in perspective views and in FIGS. 7 and 8 in two different side views. In the figures—instead of the entire cooling structure 20—the several fluid channels 30 of the cooling structure 20 are shown. In other words, the fluid channels 30 are shown here without the metallic body in which they are embedded. Furthermore, seen in the stacking direction S, a feed structure 50 adjoins the bottom side of the distribution structure 40. Accordingly, viewed in stacking direction S, the distribution structure is arranged between the cooling structure and the feed structure. Such a feed structure 50 is preferably provided to predetermine a first main flow direction HS1. For example, the feed structure is channel-shaped. Furthermore, the feed structure 50 comprises at least one inlet and one outlet (not shown here) to which a fluid circuit can be connected or a cooling fluid supply and a cooling fluid disposal. The distribution structure 40 is preferably designed in such a way that it diverts the fluid from a flow flowing along the first main flow direction HS1 into the cooling structure 20 or introduces it there. Furthermore, for the sake of clarity, the figures only show a single row of fluid channels 30. Preferably, it is provided that several rows are arranged next to each other or one behind the other in a direction perpendicular to the row direction RR and parallel to the main extension plane HSE, and each of these rows is supplied with the fluid via a corresponding distribution structure 40, for example a single distribution structure. Preferably, these several rows extend completely via the outer side A of the cooling structure 20 facing the distribution structure.

In particular, it is provided that several fluid channels 30 are arranged next to each other. In particular, in the illustrated embodiment, the fluid channels 30 are arranged along a row which, in the illustrated embodiment example, runs essentially perpendicular to the first main flow direction HS1. In principle, it is also conceivable that the row runs along a row direction RR which is inclined at an angle of between 0 and 90° relative to the first main flow direction HS1. Preferably, the angle is less than 45°.

In the embodiment illustrated in FIGS. 4 to 8, it is provided that the distribution structure 40 deflects the fluid in such a way that at least part of the fluid is first deflected from a first main flow direction HS1 into a transverse direction Q running parallel to the row direction before it is directed into the inlet openings 31. In addition, the fluid is deflected in the direction of the inlet opening 31 in the direction of the cooling structure 20, i.e. upwards. As a result, the distribution structure can supply several inlet openings 31 of different fluid channels 30 with a fluid at the same temperature. For this purpose, the inlet part 41 is designed as a wall-like structure which, in the embodiment shown, runs essentially parallel to the row direction RR. Preferably, it is provided that the feed structure 50 feeds the fluid to only a part of the distribution structure 40. In the illustrated embodiment, as seen along the first main flow direction HS1, essentially a first part, in particular a left half, of the inlet part 41 is flowed against by the cooling fluid. However, the complete row of fluid channels 30 is supplied with the fluid by means of the distribution structure 40. Preferably, the inlet part comprises a ramp-like structure that is inclined as seen in the row direction RR, in particular inclined with respect to the main extension plane HSE.

After passing through the fluid channels 30, the fluid leaves the cooling structure 20 via the outlet openings 32 and is guided into the outlet part 42 of the distribution structure. The outlet part 42 of the distribution structure 40 is also designed as a wall-like structure that runs substantially parallel to the row direction RR. In particular, it is provided that the outlet part 42 is configured such that it collects the fluid emerging from the outlet openings and diverts it in a second main flow direction HS2 back into the feed structure 50. For example, the outlet part 42 comprises a ramp-like structure which is inclined in the row direction RR, in particular inclined in the opposite direction to the ramp-like structure in the inlet part 41 of the distribution structure 40. Furthermore, it is provided that the first main flow direction HS1 and the second main flow direction HS2 are offset parallel to each other. In other words: After leaving the distribution structure 40, the flow of the fluid is offset sideways or laterally with respect to the flow when flowing towards the distribution structure 40.

In the embodiment shown, the inlet part 41 of the distribution structure 40 is arranged ahead of the outlet part 42 of the distribution structure 40, as seen along the first main flow direction HS1. However, it is also conceivable that the outlet part 42 is arranged ahead of the inlet part 31 of the distribution structure 40, as seen along the first main flow direction HS1.

The individual fluid channels 30 are preferably U-shaped, wherein the U-shaped fluid channel 30 has two limb regions 34 extending substantially perpendicular to the main extension plane HSE and a transverse region 33 joining the two limb regions 34. In particular, the transverse region 33 serves to deflect the fluid and is closest to the secondary layer 13 or the ceramic layer 11 in the installed state. Preferably, a distance between the transverse region 33 and a ceramic layer 11 or secondary layer 13 adjacent to the cooling structure 20 has a value between 0.2 and 1.5 mm, more preferably between 0.4 and 1 and most preferably between 0.6 mm and 0.8 mm. Preferably, the fluid channels 30, in particular their limb regions 34, are designed in such a way that the fluid is swirled within the fluid channels 30. For this purpose, it is provided, for example, that an opening cross-section Q1, Q2 of the limb regions 34, which courses parallel to the main extension plane HSE, is displaced laterally along a flow direction of the fluid within the fluid channel 30, in particular within the limb region 34. The limb region 34 comprises a first subsection T1 with a first opening cross-section Q1 and a second subsection T2 with a second opening cross-section Q2, wherein the first opening cross-section Q1 is offset from the second opening cross-section Q2 by an offset distance V when viewed in a direction parallel to the main extension plane HSE. Preferably, the first opening cross-section Q1 and the second opening cross-section Q2 are the same size. However, it is also conceivable that the first opening cross-section differs from the second opening cross-section. In particular, the first subsection T1 and the second subsection T2 are each assigned to metal layers that are stacked on top of each other during production, for example. The individual metal layers can be of the same thickness or differ in terms of their thickness. It is also conceivable, for example, that the thickness of the individual layers decreases and/or increases in the direction of the component side.

In particular, it is provided that the first opening cross-section Q1 and the second opening cross-section Q2 are offset relative to each other in a direction parallel to the first main flow direction HS1 or the second main flow direction HS2 and in a direction parallel to the row direction RR, i.e. in two directions which are not parallel to each other. Preferably, a ratio of an overlap area, in which the first opening cross-section Q1 and the second opening cross-section Q2 are arranged one above the other as viewed in the stacking direction S, and the first opening cross-section Q1 or the second opening cross-section Q2 has a value between 0.5 and 0.9, more preferably between 0.5 and 0.8 and most preferably between 0.5 and 0.7. In particular, it is conceivable that the opening cross-section of the inlet opening and/or the outlet opening is larger than the first opening cross-section and/or the second opening cross-section. This allows a funnel-like inlet area and outlet area to be formed for the fluid channel.

However, it is also conceivable that the first opening cross-section Q1 and the second opening cross-section Q2 are of different sizes. Preferably, the first and second opening cross-sections are designed in such a way that they form an essentially spiral course for the fluid channel 30. The fluid channels 30 can be realised, for example, by stacking metal layers, i.e. at least a first metal layer 11 and a second metal layer 12, with corresponding openings or by a 3D printing process. Furthermore, it is provided that the inlet opening 13 has a first opening cross-section, the diameter and/or edge length of which has a value between 0.1 mm and 2.5 mm, more preferably between 0.5 mm and 1.5 mm and most preferably essentially of 1 mm. It is preferably provided that the first opening cross-section Q1 or the second opening cross-section Q2 do not change within the limb regions 34 of the fluid channel 30.

Furthermore, it is provided that a further distance A2 between two neighbouring limb regions, preferably of the same fluid channel, has a value between 0.1 mm and 5 mm, more preferably between 0.2 mm and 2 mm and most preferably substantially 1.5 mm. The further distance A2 between two centres of the first cross-sectional opening Q1 or second cross-sectional opening Q2 is measured at the same height as seen in the stacking direction S.

In addition to the heat sinks 20 or carrier substrates 1 described above, other heat sinks 20 with different geometries are also conceivable. For example, it is even conceivable that the heat sink 20 is formed from an essentially flat, unstructured metal body 20. However, a structured manner of heat sink 20 is preferable, which is, for example, open to its cooling side and/or at least partially closed or completely closed. Preferably, microchannels are formed in the manufactured heat sink 20, through which a cooling fluid, preferably a cooling liquid, can then be channelled during operation. This allows the heat generated, for example on the component side 4 or caused by a laser diode mounted on the connecting area 30, to be dissipated. In order to prevent the heat sink 20, which is made of a metal, from corroding over time, it is provided that the heat sink 20 at least partially has an anti-corrosion layer 30. Otherwise, corrosion would cause the heat sink 20 to either leak and/or clog the microchannels or cooling areas.
1 Carrier element
4 Electrical component
5 Component side
6 Cooling side
7 web-like element
11 first metal layer
12 second metal layer
13 third metal layer
14 lower cover layer
15 upper cover layer
21 first part
22 second part
24 further void
25 Fin structure
30 Connecting area
33 Transverse region
34 Limb region
40 Distribution structure
41 inlet part
42 outlet part
50 Feed structure
70 Metal-ceramic substrate
71 Ceramic element
72 component metallisation
75 intermediate layer
73 Secondary layer
A1 Distance
A2 further distance
S Stacking direction
T1 first subsection
T2 second subsection
Q Transverse direction
Q1 first opening cross-section
Q2 second opening cross-section
M Centre axis
D Thickness
V Offset distance
RR row direction
HS1 first main flow direction
HS2 second main flow direction
HSE main extension plane

1-13. (canceled)

14. A carrier substrate (1) for electrical components (4), comprising:
a heat sink (20), and
a ceramic element (71), wherein the ceramic element (71) is bonded to the heat sink (20) at least in sections,
wherein a bonding layer free of solder material is formed in the manufactured carrier substrate (1) between the heat sink (20) and the ceramic element (71), and
wherein an adhesion agent layer of the bonding layer has a sheet resistance which is greater than 5 ohm/sq, characterized in that the heat sink (20) is bonded to the ceramic element (71) via a backside metallization (74) and the adhesion agent layer is formed between the backside metallization (74) and the ceramic element (71).

15. The carrier substrate (1) according to claim 14, wherein the ceramic element (71) comprises a material composition which cannot be bonded via a direct bonding method.

16. The carrier substrate (1) according to claim 14, wherein the ceramic element comprises Si₃N₄.

17. The carrier substrate (1) according to claim 14, wherein a grain size in the backside metallization (74) is different from a grain size in the heat sink (20).

18. The carrier substrate (1) according to claim 14, wherein the ceramic element has a thickness which is less than 300 μm.

19. The carrier substrate (1) according to claim 14, wherein the heat sink is formed from at least a first metal layer (21) and a second metal layer (22) which are joined on top of one another by means of a direct bonding method, wherein the first metal layer (21) and/or the second metal layer (22) have recesses which form a cooling channel in the manufactured carrier substrate (1).

20. The carrier substrate (1) according to claim 14, a thickness of the bonding layer or adhesion agent layer, measured in the stacking direction (S), averaged over a plurality of measuring points within a predetermined area or in a plurality of areas which course or run parallel to the main extension plane, has a value which is less than 1000 nm.

21. The method of manufacturing a carrier substrate (1) according to claim 14, comprising:
bonding the backside metallization (74) to the ceramic element (71) by means of hot isostatic pressing for forming a metal-ceramic substrate,
providing the heat sink (20), and
bonding the heat sink (20) to the backside metallization (74) by means of a direct bonding method.

22. The method according to claim 21, wherein a void in a first metal layer (21) and/or a second metal layer (22) is realized by means of etching, eroding and/or milling and at least the first metal layer (21) and the second metal layer (22) are joined together by means of a direct copper bonding (DCB) process to form the heat sink (20), wherein the bonding of the at least first metal layer (21) and/or second metal layer (22) to the backside metallization and the bonding of the first metal layer (21) and the second metal layer (22) to form the heat sink (20) are performed at least partially simultaneously.

23. The method according to claim 22, wherein an active metal layer for forming the bonding layer is arranged between the ceramic element (71) on the one hand and a component metallization (72) and/or the backside metallization (74) on the other hand.

24. The method according to claim 23, wherein a ratio between a thickness of the active metal layer and a thickness of the first metal layer (21) and/or second metal layer (22) has a value between 0.0001 and 0.005.

25. The method according to claim 21, wherein a metal-ceramic substrate (70) is produced by hot isostatic pressing and thereafter the bonding of the heat sink (20) to the backside metallization (74) is realized.
